(19) United States
(12) Patent Application Publication
(10) Pub. No.: US 2002/0090783 A1
(43) Pub. Date: Jul. 11, 2002

(54) Use of atomic oxidation for fabrication of oxide-nitride-oxide stack for flash memory devices

(76) Inventors: Kevin L. Beaman, Boise, ID (US); Ronald A. Weimer, Boise, ID (US)

Correspondence Address: DICKSTEIN SHAPIRO MORIN & OSHINSKY LLP, 2101 L STREET NW, WASHINGTON, DC, 20037-1526, US

(21) Appl. No.: 10/020,209

(22) Filed: Dec. 18, 2001

Related U.S. Application Data
(62) Division of application No. 09/653,281, filed on Aug. 31, 2000.

(51) Int. Cl. H01L 21/336

(52) U.S. Cl. 438/257

(57) ABSTRACT

The present invention provides a flash memory cell utilizing an ambient containing atomic oxidation for fabrication of a second or top oxide layer in a oxide-nitride-oxide insulating structure. The second or top oxide layer is grown utilizing atomic oxygen containing ambients. A silicon nitride is thus oxidized substantially faster than standard steam or oxygen ambients.

### FIELD OF THE INVENTION

The present invention relates to flash memory devices such as electrical erasable programmable read only memory devices (“EEPROMs”). More particularly, the present invention relates to flash memory devices utilizing atomic oxidation for fabrication of a top oxide layer in a oxide-nitride-oxide (“ONO”) insulating structure.

### DISCUSSION OF THE RELATED ART

Nonvolatile memory devices include flash EEPROMs. FIG. 1 represents the relevant portion of a typical flash memory cell 10. The memory cell 10 typically includes a source region 12, a drain region 14 and a channel region 16 in a substrate 18 and a stacked gate structure 20 overlying the channel region 16. The stacked gate 20 includes a thin gate dielectric layer 22 (commonly referred to as the tunnel oxide) formed on the surface of the substrate 18. The stacked gate 20 also includes a polysilicon floating gate 24 which overlies the tunnel oxide 22 and an interpoly dielectric layer 26 which overlies the floating gate 24. The interpoly dielectric layer 26 is often a multilayer insulator such as an ONO layer having two oxide layers 26a and 26b sandwiching a nitride layer 26c. Lastly, a polysilicon control gate 28 overlies the interpoly dielectric layer 26. The channel region 16 of the memory cell 10 conducts current between the source region 12 and the drain region 14 in accordance with an electric field developed in the channel region 16 by the stacked gate structure 20.

Generally speaking, a flash memory cell is programmed by inducing hot electron injection from a portion of the substrate, such as the channel region near the drain region, to the floating gate 24. Electron injection carries negative charge into the floating gate. The injection mechanism can be induced by grounding the source region and a bulk portion of the substrate and applying a relatively high positive voltage to the control gate 28 to create an electron attracting field and applying a positive voltage of moderate magnitude to the drain region in order to generate “hot” (high energy) electrons. After sufficient negative charge accumulates on the floating gate, the negative potential of the floating gate raises the threshold voltage (Vₜ) of the illustrated field effect transistor (FET) and inhibits current flow through the channel region through a subsequent “read” mode. The magnitude of the read current is used to determine whether or not a flash memory cell is programmed. The act of discharging the floating gate 24 of a flash memory cell is called the erase function. The erase function is typically carried out by a Fowler-Nordhieim tunneling mechanism between the floating gate 24 and the source region 12 of the transistor (source erase or negative gate erase) or between the floating gate 24 and the substrate 18 (channel erase). A source erase operation is induced by applying a high positive voltage to the source region 12 and a ground potential to the control gate 28 and the substrate 18 while floating the drain of the respective memory cell.

Referring again to FIG. 1, conventional programming and erasing operations for the flash memory cell 10 occur as follows. The memory cell 10 is programmed by applying a relatively high voltage V_{G} (e.g., approximately 8.5 volts) to the control gate 28 and a moderately high voltage V_{D} (e.g, approximately 4 volts) to the drain region 14 in order to produce “hot” electrons in the channel region 16 near the drain region 14. The hot electrons accelerate across the tunnel oxide 22 and into the floating gate 24 and become trapped in the floating gate 24 since the floating gate 24 is surrounded by insulators (the interpoly dielectric 26 and the tunnel oxide 22). As a result of the trapped electrons, the threshold voltage Vt of the memory cell 10 increases by about 3 to 5 volts. This change in the threshold voltage (and thereby tie channel conductance) of the memory cell 10 created by the trapped electrons causes the cell to be programmed.

To read tie flash memory cell 10, a predetermined voltage V_{G} that is greater than the threshold voltage of an unprogrammed cell, but less than the threshold voltage of a programmed cell, is applied to the control gate 28. If the memory cell 10 conducts, then the memory cell 10 has not been programmed (the cell 10 is therefore at a first logic state, e.g., a zero “0”). Likewise, if the memory cell 10 does not conduct, then the memory cell 10 has been programmed (the cell 10 is therefore at a second logic state, e.g., a one “1”). Consequently, it is possible to read each cell 10 to determine whether or not it has been programmed (and therefore identify its logic state).

In order to erase the flash memory cell 10, a relatively high voltage Vₛ (e.g., approximately 8.5-10 volts) is applied to the source region 12 and the control gate 28 is held at about (V_{G}=−8.5), while the drain region 14 is allowed to float. Under these conditions, a strong electric field is developed across the tunnel oxide 22 between the floating gate 24 and the source region 12. The electrons that are trapped in the floating gate 24 flow toward and cluster at the portion of the floating gate 24 overlying the source region 22 and are extracted from the floating gate 24 and into the source region 12 by way of Fowler-Nordheim tunneling through the tunnel oxide 22. Also, a channel erase structure where electrons are “pulled” through the entire gate/channel structure region is possible. Consequently, as the electrons are removed from the floating gate 24, the memory cell 10 is erased.

The ONO interpoly dielectric layer 26 has a number of important functions including insulating the control gate from the floating gate. When forming an ONO interpoly dielectric layer, there are a number of concerns. For example, the top oxide layer of an ONO interpoly dielectric layer is conventionally formed by a high temperature, wet oxidation process. Such a process involves oxidizing the nitride layer in steam and oxygen at high temperatures of about 950° C., for a long duration of time, typically about 2 hours. The lengthy oxidation process is necessary because the actual thickness that is deposited is only about 1% of the targeted thickness. In other words, in attempting to grow a top oxide layer of about 80 Å, only about 0.8 Å will actually grow on the nitride layer. This relatively long process time and relatively high temperature is unwanted, as it may, for example, degrade the tunnel oxide as well as increase cost.

In view of the above, there is a need for more efficient and reliable method of making flash memory cells.

### SUMMARY OF THE INVENTION

The present invention relates to flash memory cell utilizing an ambient containing atomic oxidation for fabrication of a second or top oxide layer in a oxide-nitride-oxide insulating structure. The second or top oxide layer is grown utilizing atomic oxygen at a temperature of about 850° C. to about 1100° C., preferably at a temperature less than 900° C., for about 1 second to about 10 minutes. The invention provides a top oxide layer, having a resulting thickness of at least about 60% of a targeted thickness of the top oxide layer on the nitride layer, as compared to a typical resulting thickness of about 1% of the targeted thickness of the top oxide layer in conventional methods, such as wet oxidation, not utilizing atomic oxygen.

The above advantages and features of the invention will be more clearly understood from the following detailed description which is provided in connection with the accompanying drawings.

### BRIEF DESCRIPTION OF THE DRAWINGS

FIG. 1 illustrates a cross-sectional view of relevant portions of a conventional flash memory cell;

FIG. 1A illustrates a furnace for forming the flash memory cell of the present invention;

FIGS. 2A to 2H illustrates cross-sectional views illustrating a flash memory cell fabrication method according to one exemplary embodiment of the present invention; and

FIG. 3 illustrates a processor based system utilizing a flash memory constructed in accordance with an exemplary embodiment of the present invention.

### DETAILED DESCRIPTION OF THE INVENTION

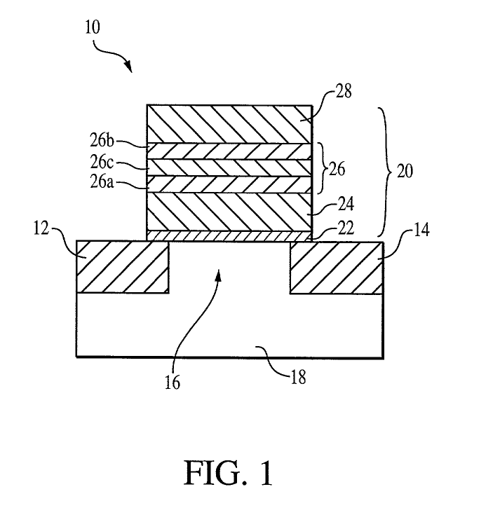

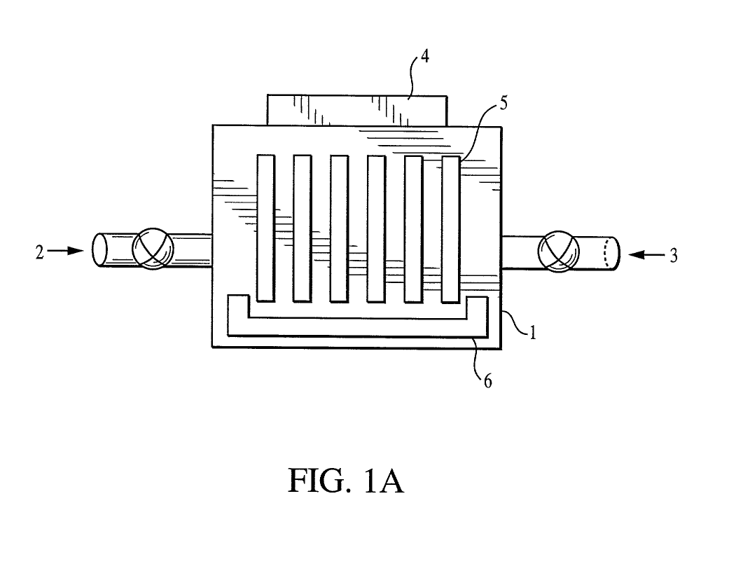

The present invention will be described as set forth in FIGS. 1A, 2A-2H and 3. Other embodiments may be utilized and structural or logical changes may be made without departing from the spirit or scope of the present invention. Although the invention is illustrated in connection with a single flash memory cell, it a will be readily apparent that a plurality of flash memory cells can be formed on a semiconductor substrate with the present invention. Also, although the present invention is described in connection with a flash memory cell, it will be readily apparent that the invention may be practiced in any integrated circuit device. Further, although the present invention is described in terms of LPCVD, any other deposition processes can be utilized. Still further, although exemplary process conditions for forming various material layers are described below, these are only representative and are not meant to be considered as limiting the invention. Like items are referred to by like reference numerals throughout the drawings.

The term “substrate” used in the following description may include any semiconductor-based structure that has an exposed silicon surface. Structure must be understood to include silicon, silicon-on insulator (SOI), silicon-on sapphire (SOS), doped and undoped semiconductors, epitaxial layers of silicon supported by a base semiconductor foundation, and other semiconductor structures. The semiconductor need not be silicon-based. The semiconductor could be silicon-germanium, germanium, or gallium arsenide. When reference is made to substrate in the following description, previous process steps may have been utilized to form regions or junctions in or over the base semiconductor or foundation.

FIG. 1A schematically illustrates a furnace 1 which can be used in forming oxide and nitride films on silicon wafers or other substrates on which dielectric layers are to be formed. Although an exemplary furnace is illustrated, the dielectric layers of the present invention can also be formed in a single wafer system, a batch furnace system, a rapid thermal system, a fast ramp system or combinations of the above-mentioned systems. Furnace 1 is provided with one or more gas feeds 2 for providing reaction and other ambient gases to the furnace chamber. Chamber pressure is maintained by pumping through vacuum port 3. A heater 4, typically operating under computer control, maintains the chamber at desired temperatures and alters the temperature of the chamber in a controlled manner. One or more substrates 5 are loaded-onto a carrier or boat 6 for transport into and out of the furnace. The substrates may be, for example, silicon wafers at a intermediate stage of flash memory manufacture in which lower capacitor electrodes have been formed from doped polysilicon in contact with the appropriate source/drain regions of transfer field effect transistors formed in and on the silicon wafers.

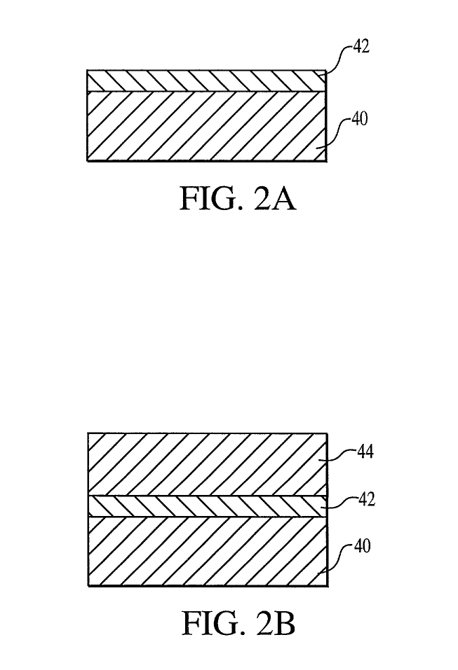

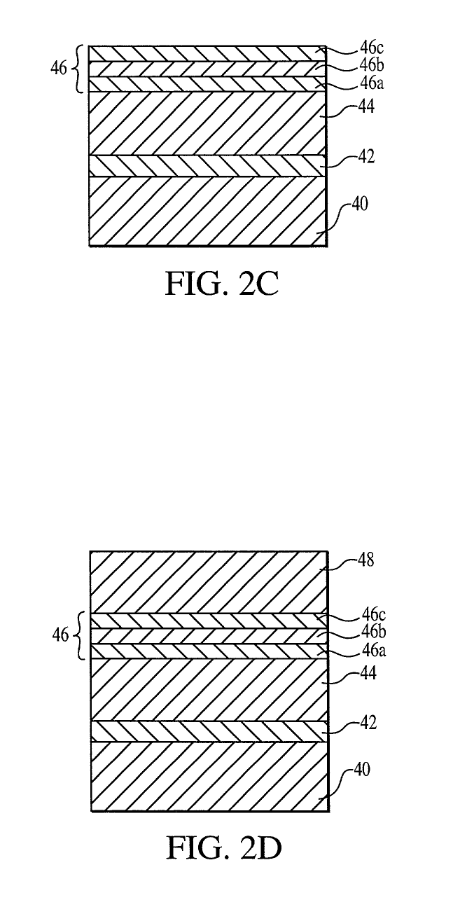

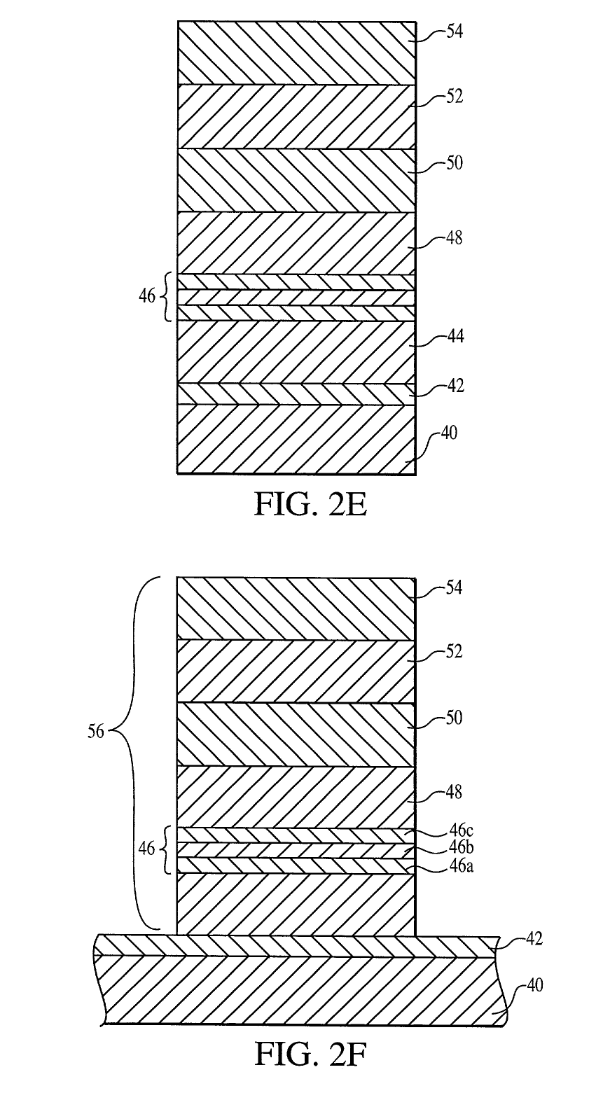

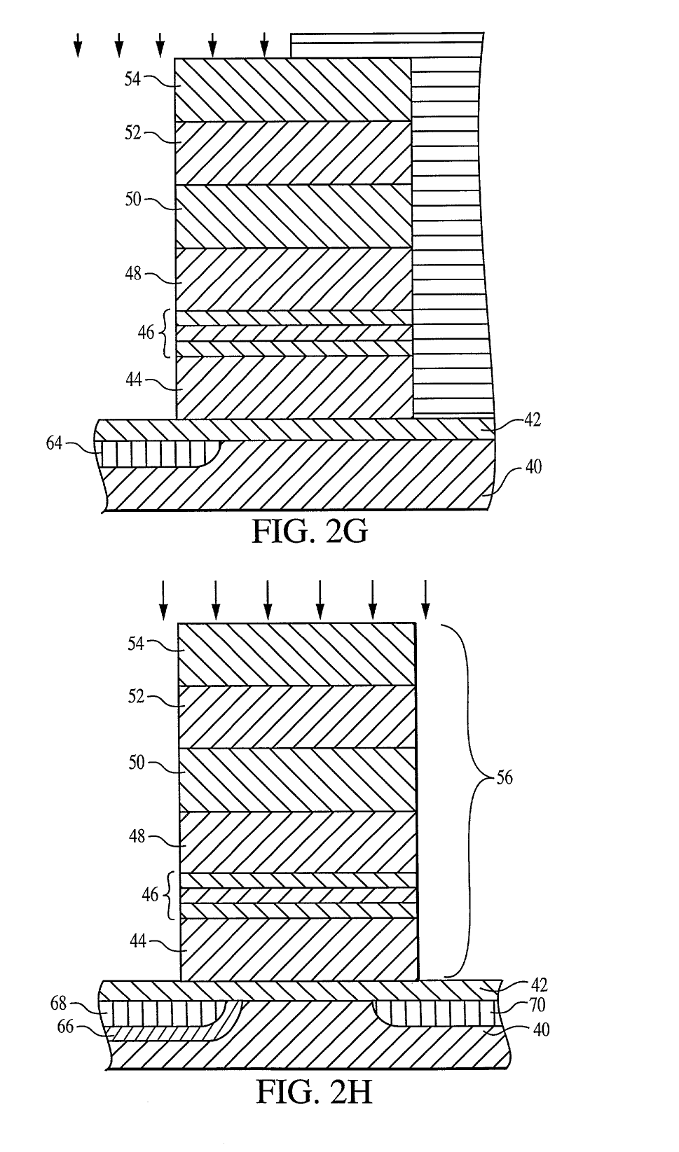

Referring now to FIG. 2A, a device constructed in accordance with the invention will now be described. A P-type substrate 40 is provided and a thin tunnel oxide layer 42 is formed over the substrate 40, the oxide layer having a thickness of, for example, about 50 Å to about 150 Å using a thermal growth process in a dry oxidation furnace. For instance, the tunnel oxide layer 42 can be formed via dry oxidation at a temperature of about 1050° C., under an atmosphere of oxygen at about 1.33 sccm, HCI at about 70 sccm and argon at about 12 sccm. Alternatively, the tunnel oxide layer 42 can be formed from oxynitride.

Referring to FIG. 2B, a phosphorus doped polysilicon is deposited via CVD to form a phosphorous doped polysilicon layer 44. The deposition may performed at a temperature of about 530° C., pressure of 400 mTorr, under an atmosphere of SiH₄ at 2000 sccm, and a mixture of 1% by weight PH₃ in helium at about 22 sccm.

A multi-layer interpoly dielectric 46 is then formed over the surface of the polysilicon layer 44, as illustrated in FIG. 2C. This layer 46 is often called an interpoly dielectric since it is sandwiched between the phosphorus doped polysilicon layer 44 (first polysilicon layer constituting the floating gate for a flash memory cell) and a second polysilicon layer (not shown in FIG. 2C) which forms the control gate for the cell. The interpoly dielectric 46 is preferably a three layer region of oxide/nitride/oxide (a so called “ONO” layer) and typically has a total thickness of about 120 Å to about 400 Å. Generally speaking, the ONO layer 46 is formed by the sequential depositions or growth of oxide, nitride and oxide, as further described below, to form a dielectric layer in which the nitride is sandwiched between a bottom oxide layer and top oxide layer.

Specifically referring to FIG. 2C, a first or bottom oxide layer 46a is deposited using, for example, CVD techniques. Note, although a deposition method is illustrated to fabricate the first oxide layer, it can also be thermally grown. For example, a bottom oxide layer 46a may be deposited at a temperature of about 750° C. under SiH₄ at 20 sccm, N₂O at 12 sccm, with a carrier gas and a pressure of 600 mTorr via LPCVD on the first polysilicon layer 44. The bottom oxide layer may have a suitable thickness, for example, from about 40 Å to about 60 Å, but typically the thickness is about 50 Å. A nitride layer 46b is next deposited, for example, using CVD techniques. For example, nitride is deposited at a temperature of about 760° C. using NH₃ at 600 sccm, SiH₂Cl₂ at 100 sccm and a pressure of 330 mTorr to form a nitride layer 46b. The nitride layer 46b may have a suitable thickness, for example, from about 60 Å to about 100 Å, preferably from about 70 Å to about 90 Å, but typically the thickness is about 80 Å.

The second or top oxide layer 46c is grown at a temperature of about 850° C. to 1100° C., preferably at a temperature less than about 900° C., for about 1 second to about 10 minutes, using a gas ambient containing atomic oxygen. The atomic oxygen can be supplied by in situ steam generation. In other words, a combination of O₂ and H₂ at a hot wafer surface , or a surface in close proximity, is utilized wherein steam and atomic oxygen is formed and available for oxidation. Also, atomic oxygen can be supplied by an ozone source, plasma source, microwave source or photoexcitation. Depending on the targeted thickness, for instance 80 Å, the thickness of the top oxide layer is about 48 Å. Targeted thickness is defined herein as any suitable and/or desired thickness for the top oxide layer 46c. Preferably, the top oxide layer is formed to a thickness of about 20 Å to about 80 Å. As a result of the conditions used to form the top oxide layer 46c, the resulting oxide layer will be at least about 60% of the targeted thickness of the top oxide layer on the nitride layer 46b, as compared to a typical thickness of about 1% to 3% of the targeted thickness in a conventional method, such as wet oxidation, not utilizing atomic oxygen.

Referring to FIG. 2D, after the ONO layer 46 is formed, the second polysilicon layer is deposited. Specifically, a phosphorus doped amorphous polysilicon layer is deposited via CVD to form a doped polysilicon layer 48 at about 530° C., 400 mTorr, SiH₄ at 2,000 sccm, and a mixture of 1% by weight PH₃ in helium at about 75 sccm. Alternatively, the the second polysilicon layer 48 can be deposited by LPCVD followed by ion implantation of a dopant such as phosphorus.

Referring to FIG. 2E, in one exemplary embodiment a tungsten silicide layer 50 is next deposited via, for example, LPCVD. The tungsten silicide layer 50 provides a lower resistance contact for improved flash memory cell performance. Poly-cap layer 52 is next deposited over the tungsten silicide layer 50. The poly-cap layer 52 is about 500 Å thick, and is formed via, for example, LPCVD. The poly-cap layer 52 can be used to prevent any potential peeling or cracking of the underlying tungsten slicide 50. A capping layer 54, for example, of SiON is deposited over the poly-cap layer 52. The capping silicon oxynitride layer 54 provides an anti-reflective coating at masking and also acts as a masking layer for subsequent etching.

Referring to FIG. 2F, after the second polysilicon layer 48, the tungsten silicide layer 50, the poly-cap layer 52 and the capping layer 54 have been formed (a plurality of word lines for the memory cells can be defined in this manner) etching is performed to define one or more pre-stack structures. The etching may be achieved by depositing and defining a photoresist masking layer using standard lithography procedures. This is generally termed the gate mask and gate etch. Subsequently, a number of successive etching steps are performed to define one or more stack structures 56.

The gate mask and gate etch are performed as follows. First, a resist (not shown) is applied, selectively exposed to radiation and developed whereby various portions removed (either the exposed or unexposed portions). Next, the etching steps take place in a multi-chamber etch tool wherein a silicon oxynitride capping layer 54 is first selectively etched with a fluorinated chemistry such as CHF₃—O₂ in an oxide chamber. The exposed poly-cap layer 52 and the tungsten silicide layer 50 are then etched with SF₆/HBr (or alternatively, SF₆/Cl₂ or Cl₂—O₂) and the exposed second polysilicon layer 48 is then etched with HBr—O₂ in a poly chamber. Etching steps are preferably formed in an integrated process in which the wafers are not exposed to atmosphere when they are transferred from one chamber to another.

Once the second polysilicon layer 48, the tungsten silicide layer 50, the poly-cap layer 52 and the capping layer 54 have been removed, a self aligned etch (“SAE”) is performed to remove the ONO layer 46 and the phosphorus doped polysilicon layer (first polysilicon layer) 44 in the regions that are not covered by the pre-stack structure (formed by the unremoved second polysilicon layer 48, tungsten silicide layer 50, poly-cap layer 52 and capping layer 54). The SAE etch is a two step etch process in which the ONO layer 46 is first removed using, for example, a CF₄—O₂ RIE etch. The second phase of the SAE etch is the removal of the exposed first polysilicon layer 44 to thereby further define the floating gate structures for each respective word line. The polysilicon etch includes, for example, an HBr—O₂ or a HBr—Cl₂—O₂ RIE etch chemistry. The gate etch and SAE serve to define the stack structure 56.

The fabrication of the flash memory cells is then completed by forming the source and drain regions by, for example, ion implantation. During the formation of the source and drain regions, the stacked gate structure 56 serves as a self-aligning mechanism. Specifically referring to FIG. 2G, resist 62 is applied and selectively stripped followed by performing a first ion implantation using phosphorus (1×10¹⁴ ions/cm² at 60 KeV) to form an N-type source region 64 (double diffused implant). Referring to FIG. 2H, resist 62 is removed followed by performing a second ion implantation using arsenic (5×10¹⁴ ions/cm² at 40 KeV) to form deep N-type source region 66, shallow N-type source region 68 and N-type drain region 70 (modified drain diffusion). Annealing completes the formation of the source and drain regions.

Hence, the present invention provides a flash memory cell utilizing atomic oxidation for fabrication of a second or top oxide layer in a oxide-nitride-oxide insulating structure. The second or top oxide layer is deposited utilizing atomic oxygen at a temperature of about 850° C. to about 1100° C., preferably at a temperature of less than about 900° C., for about 1 second to about 10 minutes. The invention provides a top oxide layer, having a resulting thickness of at least about 60% of a targeted thickness of the top oxide layer on the nitride layer, as compared to a typical resulting thickness of about 1% of the targeted thickness of the top oxide layer in conventional methods, such as wet oxidation, not utilizing atomic oxygen.

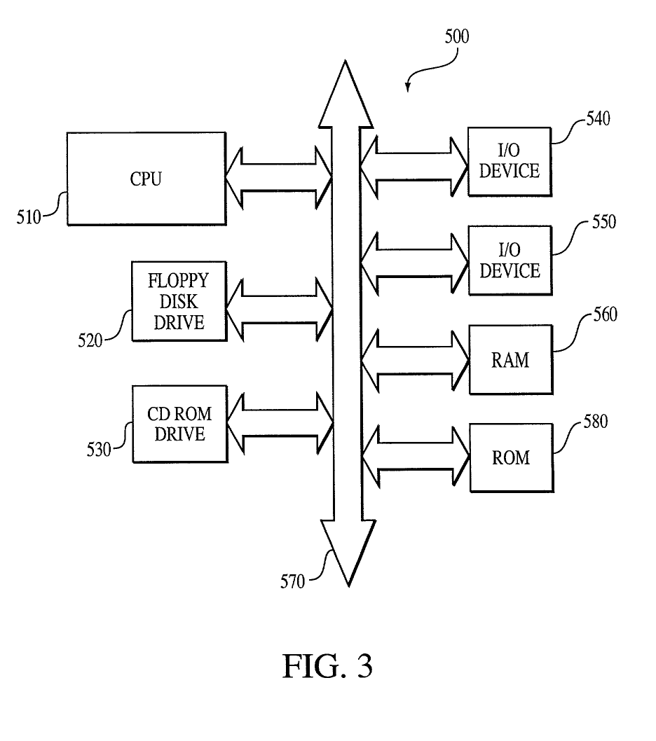

A processor system which may employ at least one memory cell having an ONO structure of the invention is illustrated in FIG. 3. As shown in FIG. 3, the processor system, such as a computer system, for example, comprises a central processing unit (CPU) 510, for example, a microprocessor, that communicates with one or more input/output (I/O) devices 540, 550 over a bus 570. The computer system 500 also includes random access memory (RAM) 560, a read only memory (ROM) 580 and may include peripheral devices such as a floppy disk drive 520 and a compact disk (CD) ROM drive 530 which also communicates with CPU 510 over the bus 570. The RAM 560 may be constructed as an integrated circuit which includes the ONO structure 46 as described above. It may also be desirable to integrate the processor 510 and memory 560 on a single IC chip.

Although the invention has been described above in connection with exemplary embodiments, it is apparent that many modifications and substitutions can be made without departing from the spirit or scope of the invention. Accordingly, the invention is not to be considered as limited by the foregoing description, but is only limited by the scope of the appended claims.

What is claimed as new and desired to be protected by Letters Patent of the United States is:

1. A method of forming a flash memory cell, comprising:
forming a tunnel oxide on a substrate;
forming a first conductor layer over the tunnel oxide;
forming an insulating layer over the first conductor layer, the insulating layer comprising a first oxide layer over the first conductor layer, a nitride layer over the first oxide layer, and a second oxide layer over the nitride layer, wherein the second oxide layer is formed by oxidizing said nitride layer with an ambient containing atomic oxygen;
forming a second conductor layer over the insulating layer;
etching at least the first conductor layer, the second conductor layer and the insulating layer, thereby defining at least one stacked gate structure; and
forming a source region and a drain region in the substrate on opposite side of said stacked gate structure, thereby forming at least one memory cell.

2. The method of claim 1 wherein said second oxide layer is grown at a temperature of about 850° C. to about 1100° C.

3. The method of claim 1 wherein said second oxide layer is grown at a temperature of less than about 900° C.

4. The method of claim 1 wherein said second oxide layer is grown for about 1 second to about 10 minutes.

5. The method of claim 1 wherein said second oxide layer is formed to at least about 60% of a targeted thickness.

6. The method of claim 1 wherein said atomic oxygen is supplied by in situ steam generation.

7. The method of claim 1 wherein said atomic oxygen is supplied by ozone source.

8. The method of claim 1 wherein said atomic oxygen is supplied by plasma source.

9. The method of claim 1 wherein said atomic oxygen is supplied by microwave source.

10. The method of claim 1 wherein said atomic oxygen is supplied by photoexcitation.

11. The method of claim 1 wherein said second oxide layer is formed in a single wafer system.

12. The method of claim 1 wherein said second oxide layer is formed in a batch furnace system.

13. The method of claim 1 wherein said second oxide layer is formed in a rapid thermal system.

14. The method of claim 1 wherein said second oxide layer is formed in a fast ramp system.

15. The method of claim 1 wherein said second oxide layer is formed to a thickness of about 20 Å-80 Å.

16. A method of forming an ONO insulating structure comprising:
depositing a first oxide layer over an integrated circuit structure;
depositing a nitride layer over said first oxide layer; and
growing a second oxide layer over said nitride layer wherein the second oxide layer is formed by oxidizing said nitride layer in the presence of atomic oxygen.

17. The method of claim 16 wherein said second oxide layer is grown at a temperature of about 850° C. to about 1100° C.

18. The method of claim 16 wherein said second oxide layer is grown at a temperature of less than about 900° C.

19. The method of claim 16 wherein said second oxide layer is grown for about 1 second to about 10 minutes.

20. The method of claim 16 wherein said second oxide layer is formed to at least about 60% of a targeted thickness.

21. The method of claim 16 wherein said atomic oxygen is supplied by in situ steam generation.

22. The method of claim 16 wherein said atomic oxygen is supplied by ozone source.

23. The method of claim 16 wherein said atomic oxygen is supplied by plasma source.

24. The method of claim 16 wherein said atomic oxygen is supplied by microwave source.

25. The method of claim 16 wherein said atomic oxygen is supplied by photoexcitation.

26. The method of claim 16 wherein said second oxide layer is formed in a single wafer system.

27. The method of claim 16 wherein said second oxide layer is formed in a batch furnace system.

28. The method of claim 16 wherein said second oxide layer is formed in a rapid thermal system.

29. The method of claim 16 wherein said second oxide layer is formed in a fast ramp system.

30. The method of claim 16 wherein said second oxide layer is formed to a thickness of about 20 Å-80 Å.

31. A method of forming a flash memory array containing a plurality of flash memory cells, each of said plurality of flash memory cells being formed by the acts of:
forming a tunnel oxide on a substrate;
forming a first conductor layer over the tunnel oxide;
forming an insulating layer over the first conductor layer, the insulating layer comprising a first oxide layer over the first conductor layer, a nitride layer over the first oxide layer, and a second oxide layer over the nitride layer, wherein die second oxide layer is formed by oxidizing said nitride layer in the presence of atomic oxygen;
forming a second conductor layer over the insulating layer;
etching at least die first conductor layer, the second conductor layer and the insulating layer, thereby defining at least one stacked gate structure; and
forming a source region and a drain region in the substrate, thereby forming at least one memory cell.

32. The method of claim 31 wherein said second oxide layer is grown at a temperature of about 850° C. to about 1100° C.

33. The method of claim 31 wherein said second oxide layer is grown at a temperature of less than about 900° C.

34. The method of claim 31 wherein said second oxide layer is grown for about 1 second to about 10 minutes.

35. The method of claim 31 wherein said second oxide layer is formed to at least about 60% of a targeted thickness.

36. The method of claim 31 wherein said atomic oxygen is supplied by in situ steam generation.

37. The method of claim 31 wherein said atomic oxygen is supplied by ozone source.

38. The method of claim 31 wherein said atomic oxygen is supplied by plasma source.

39. The method of claim 31 wherein said atomic oxygen is supplied by microwave source.

40. The method of claim 31 wherein said atomic oxygen is supplied by photoexcitation.

41. The method of claim 31 wherein said second oxide layer is formed in a single wafer system.

42. The method of claim 31 wherein said second oxide layer is formed in a batch furnace system.

43. The method of claim 31 wherein said second oxide layer is formed in a rapid thermal system.

44. The method of claim 31 wherein said second oxide layer is formed in a fast ramp system.

45. The method of claim 31 wherein said second oxide layer is formed to a thickness of about 20 Å-80 Å.

46. A flash memory cell comprising:
a gate structure comprising:
a tunnel oxide on a substrate;
a first conductor layer over the tunnel oxide;
an insulating layer over the first conductor layer, the insulating layer comprising a first oxide layer over the first conductor layer, a nitride layer over the first oxide layer, and a second oxide layer over the nitride layer, wherein the second oxide layer has a composition formed by the oxidation of said nitride layer in the presence of atomic oxygen;
a second conductor layer over the insulating layer; and
a source region and a drain region in the substrate on opposite sides of said gate structure.

47. The memory cell of claim 46 wherein said second oxide layer is formed to a thickness of about 20 Å-80 Å.

48. A memory device comprising:
a flash memory array containing a plurality of flash memory cells, each of said plurality of flash memory cells comprising:
a gate structure comprising:
a tunnel oxide on a substrate;
a first conductor layer over the tunnel oxide;
an insulating layer over the first conductor layer, the insulating layer comprising a first oxide layer over the first conductor layer, a nitride layer over the first oxide layer, and a second oxide layer over the nitride layer, wherein the second oxide layer having a composition formed by the oxidation of said nitride layer in the presence of atomic oxygen;
a second conductor layer over the insulating layer; and
a source region and a drain region in the substrate on opposite sides of said gate structure.

49. The memory device of claim 48 wherein said second oxide layer is formed to a thickness of about 20 Å-80 Å.

50. A processor based system comprising:
a central processing unit;
a memory device coupled to said central processing unit to receive data from and supply data to said central processing unit, said memory device having a flash memory cell comprising:
a gate structure comprising:
a tunnel oxide on a substrate;
a first conductor layer over the tunnel oxide;
an insulating layer over the first conductor layer, the insulating layer comprising a first oxide layer over the first conductor layer, a nitride layer over the first oxide layer, and a second oxide layer over the nitride layer, wherein the second oxide layer having a composition formed by the oxidation of said nitride layer in the presence of atomic oxygen;
a second conductor layer over the insulating layer; and
a source region and a drain region in the substrate on opposite sides of said gate structure.

51. The system of claim 50 wherein said second oxide layer is formed to a thickness of about 20 Å-80 Å.
